(19) United States
(12) Patent Application Publication
(10) Pub. No.: US 2013/0285030 A1
(43) Pub. Date: Oct. 31, 2013

(54) COMPOUND FOR ORGANIC OPTOELECTRONIC DEVICE, ORGANIC LIGHT EMITTING DIODE INCLUDING THE SAME, AND DISPLAY DEVICE INCLUDING THE ORGANIC LIGHT EMITTING DIODE

(71) Applicant: Ja-Hyun Kim, (US)

(72) Inventors: Eun-Sun YU, Uiwang-si (KR); Young-Hoon KIM, Uiwang-si (KR); Mi-Young CHAE, Uiwang-si (KR)

(21) Appl. No.: 13/931,837

(22) Filed: Jun. 29, 2013

Related U.S. Application Data
(63) Continuation of application No. PCT/KR2011/008401, filed on Nov. 7, 2011.

(30) Foreign Application Priority Data
Dec. 31, 2010 (KR) 10-2010-0140555

(51) Int. Cl. H01L 51/00; H01L 51/50

(52) U.S. Cl. CPC H01L 51/0067; H01L 51/0072; H01L 51/50
USPC 257/40; 544/212

(57) ABSTRACT

A compound for an organic optoelectronic device, an organic light emitting diode including the same, and a display device including the organic light emitting diode, the compound being represented by the following Chemical Formula 1:

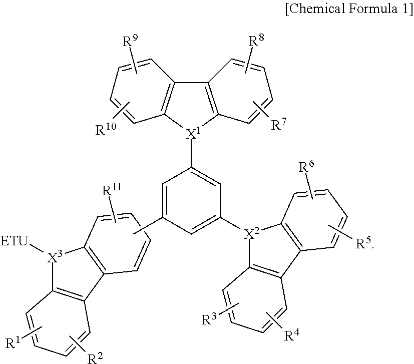

### CROSS-REFERENCE TO RELATED APPLICATIONS

This application is a continuation of pending International Application No. PCT/KR2011/008401, entitled “COMPOUND FOR ORGANIC OPTOELECTRONIC DEVICE, ORGANIC LIGHT EMITTING DIODE INCLUDING THE SAME, AND DISPLAY DEVICE INCLUDING THE ORGANIC LIGHT EMITTING DIODE,” which was filed on Nov. 7, 2011, the entire contents of which are hereby incorporated by reference.

Korean Patent Application No. 10-2010-0140555 filed on Dec. 31, 2010, in the Korean Intellectual Property Office, and entitled: “COMPOUND FOR ORGANIC OPTOELECTRONIC DEVICE, ORGANIC LIGHT EMITTING DIODE INCLUDING THE SAME, AND DISPLAY DEVICE INCLUDING THE ORGANIC LIGHT EMITTING DIODE,” is incorporated by reference herein in its entirety.

### BACKGROUND

1. Field

Embodiments relate to a compound for an organic optoelectronic device, an organic light emitting diode including the same, and a display device including the organic light emitting diode.

2. Description of the Related Art

An organic photoelectric device is a device requiring a charge exchange between an electrode and an organic material by using holes or electrons.

An organic optoelectronic device may be classified in accordance with its driving principles. One type of organic optoelectronic device is an electronic device driven as follows: excitons are generated in an organic material layer by photons from an external light source; the excitons are separated into electrons and holes; and the electrons and holes are transferred to different electrodes as a current source (voltage source).

Another type organic optoelectronic device is an electronic device driven as follows: a voltage or a current is applied to at least two electrodes to inject holes and/or electrons into an organic material semiconductor positioned at an interface of the electrodes, and the device is driven by the injected electrons and holes.

Examples of the organic optoelectronic device may include an organic photoelectronic device, an organic light emitting diode, an organic solar cell, an organic photoconductor drum, an organic transistor, and the like, which may include a hole injecting or transport material, an electron injecting or transport material, or a light emitting material.

Particularly, an organic light emitting diode (OLED) has recently drawn attention due to an increasing demand for flat panel displays. In general, organic light emission refers to conversion of electrical energy into photo-energy.

### SUMMARY

Embodiments are directed to a compound for an organic optoelectronic device, an organic light emitting diode including the same, and a display device including the organic light emitting diode.

The embodiments may be realized by providing a compound for an organic optoelectronic device, the compound being represented by the following Chemical Formula 1:

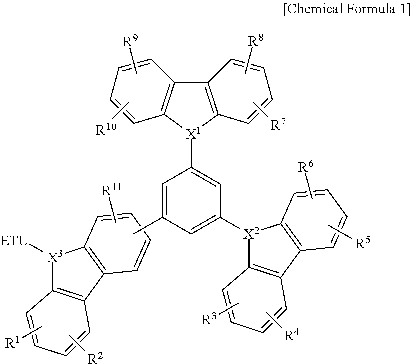

wherein, in the above Chemical Formula 1, X¹ to X³ are N, ETU is a substituted or unsubstituted C2 to C30 heteroaryl group having electron characteristics, and R¹ to R¹¹ are each independently hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

The compound for an organic optoelectronic device may be represented by the following Chemical Formula 2:

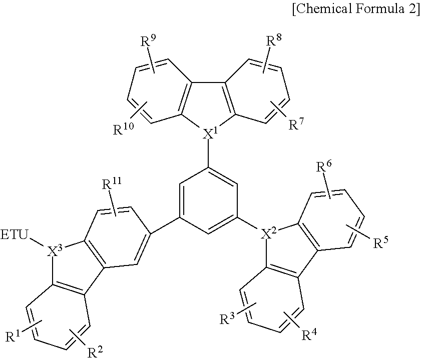

wherein, in the above Chemical Formula 2, X¹ to X³ are N, ETU is a substituted or unsubstituted C2 to C30 heteroaryl group having electron characteristics, and R¹ to R¹¹ are each independently hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

The substituted or unsubstituted C2 to C30 heteroaryl group having electron characteristics may be a substituted or unsubstituted imidazolyl group, a substituted or unsubstituted triazolyl group, a substituted or unsubstituted tetrazolyl group, a substituted or unsubstituted oxadiazolyl group, a substituted or unsubstituted oxatriazolyl group, a substituted or unsubstituted thiatriazolyl group, a substituted or unsubstituted benzimidazolyl group, a substituted or unsubstituted benzotriazolyl group, a substituted or unsubstituted pyridinyl group, a substituted or unsubstituted pyrimidinyl group, a substituted or unsubstituted triazinyl group, a substituted or unsubstituted pyrazinyl group, a substituted or unsubstituted pyridazinyi group, a substituted or unsubstituted purinyl group, a substituted or unsubstituted quinolinyl group, a substituted or unsubstituted isoquinolinyl group, a substituted or unsubstituted phthalazinyl group, a substituted or unsubstituted naphpyridinyl group, a substituted or unsubstituted quinoxalinyl group, a substituted or unsubstituted quinazolinyl group, a substituted or unsubstituted acridinyl group, a substituted or unsubstituted phenanthrolinyl group, a substituted or unsubstituted phenazinyl group, or a combination thereof.

The organic optoelectronic device may be selected from an organic photoelectric device, an organic light emitting diode, an organic solar cell, an organic transistor, an organic photo-conductor drum, and an organic memory device.

The embodiments may also be realized by providing a compound for an organic optoelectronic device, the compound being represented by one of the following Chemical Formulae 1a to 6a:

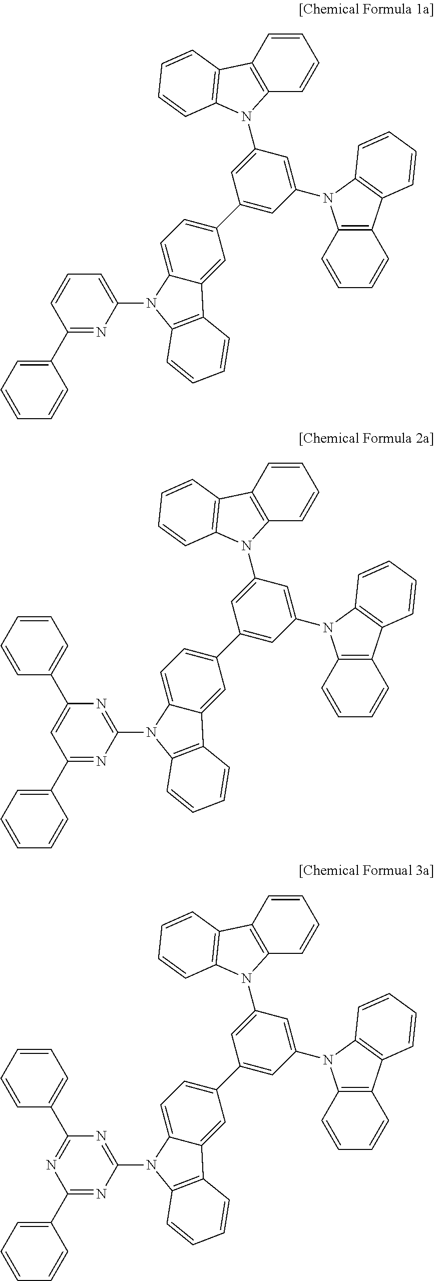 [SMILES: c1ccc(-c2cccc(-n3c4ccccc4c4cc(-c5cc(-n6c7ccccc7c7ccccc76)cc(-n6c7ccccc7c7ccccc76)c5)ccc43)n2)cc1 ; c1ccc(-c2cc(-c3ccccc3)nc(-n3c4ccccc4c4cc(-c5cc(-n6c7ccccc7c7ccccc76)cc(-n6c7ccccc7c7ccccc76)c5)ccc43)n2)cc1 ; c1ccc(-c2nc(-c3ccccc3)nc(-n3c4ccccc4c4cc(-c5cc(-n6c7ccccc7c7ccccc76)cc(-n6c7ccccc7c7ccccc76)c5)ccc43)n2)cc1]

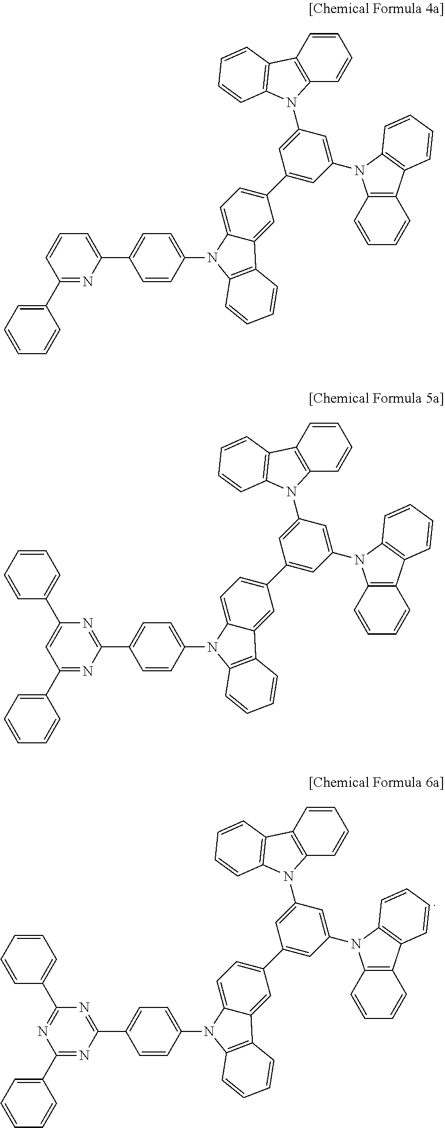 [SMILES: c1ccc(-c2cccc(-c3ccc(-n4c5ccccc5c5cc(-c6cc(-n7c8ccccc8c8ccccc87)cc(-n7c8ccccc8c8ccccc87)c6)ccc54)cc3)n2)cc1 ; c1ccc(-c2cc(-c3ccccc3)nc(-c3ccc(-n4c5ccccc5c5cc(-c6cc(-n7c8ccccc8c8ccccc87)cc(-n7c8ccccc8c8ccccc87)c6)ccc54)cc3)n2)cc1 ; c1ccc(-c2nc(-c3ccccc3)nc(-c3ccc(-n4c5ccccc5c5cc(-c6cc(-n7c8ccccc8c8ccccc87)cc(-n7c8ccccc8c8ccccc87)c6)ccc54)cc3)n2)cc1]

The embodiments may also be realized by providing an organic light emitting diode including an anode, a cathode, and at least one organic thin layer between the anode and the cathode, wherein the at least one organic thin layer includes the compound for an organic optoelectronic device according to an embodiment.

The at least one organic thin layer may be selected from an emission layer, a hole transport layer (HTL), a hole injection layer (HIL), an electron transport layer (ETL), an electron injection layer (EIL), a hole blocking layer, and a combination thereof.

The at least one organic thin layer may include an electron transport layer (ETL) or an electron injection layer (EIL), and the compound for an organic optoelectronic device may be included in the electron transport layer (ETL) or the electron injection layer (EIL).

The at least one organic thin layer may include an emission layer, and the compound for an organic optoelectronic device may be included in the emission layer.

The at least one organic thin layer may include an emission layer, and the compound for an organic optoelectronic device may be a phosphorescent or fluorescent host material in the emission layer.

The at least one organic thin layer may include an emission layer, and the compound for an organic optoelectronic device may be a fluorescent blue dopant material in the emission layer.

The embodiments may also be realized by providing a display device including the organic light emitting diode according to an embodiment.

### BRIEF DESCRIPTION OF THE DRAWINGS

Features will become apparent to those of skill in the art by describing in detail exemplary embodiments with reference to the attached drawings in which:

FIGS. 1 to 5 illustrate cross-sectional views showing organic light emitting diodes according to various embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

In the present specification, when a definition is not otherwise provided, “substituted” may refer to one substituted with a C1 to C30 alkyl group; a C1 to C10 alkylsilyl group; a C3 to C30 cycloalkyl group; a C6 to C30 aryl group; a C2 to C30 heteroaryl group; a C1 to C10 alkoxy group; a fluoro group, a C1 to C10 trifluoroalkyl group such as a trifluoromethyl group, and the like; or a cyano group.

In the present specification, when a definition is not otherwise provided, “hetero” may refer to one including 1 to 3 hetero atoms selected from the group of N, O, S, and P, and remaining carbons in one functional group.

In the specification, when a definition is not otherwise provided, “alkyl group” may refer to “a saturated group” without any alkene group or alkyne group; or “an unsaturated alkyl group” with at least one alkene group or alkyne group. The “alkene group” may refer to a substituent of at least one carbon-carbon double bond of at least two carbons, and the “alkyne group” may refer to a substituent of at least one carbon-carbon triple bond of at least two carbons. The alkyl group may be branched, linear, or cyclic.

The alkyl group may be a C1 to C20 alkyl group, and specifically a C1 to C6 lower alkyl group, a C7 to C10 medium-sized alkyl group, or a C11 to C20 higher alkyl group.

For example, a C1 to C4 alkyl group may have 1 to 4 carbon atoms and may be selected from the group of methyl, ethyl, propyl, iso-propyl, n-butyl, iso-butyl, sec-butyl, and t-butyl.

Typical examples of alkyl group may include a methyl group, an ethyl group, a propyl group, an isopropyl group, a butyl group, an isobutyl group, a t-butyl group, a pentyl group, a hexyl group, an ethenyl group, a propenyl group, a butenyl group, a cyclopropyl group, a cyclobutyl group, a cyclopentyl group, a cyclohexyl group, and the like.

“Aromatic group” may refer to a substituent including all element of the cycle having p-orbitals which form conjugation. Examples may include an aryl group and a heteroaryl group.

“Aryl group” may refer to a monocyclic or fused ring polycyclic (i.e., rings sharing adjacent pairs of carbon atoms) substituent.

“Heteroaryl group” may refer to an aryl group including 1 to 3 hetero atoms selected from the group of N, O, S, and P, and remaining carbons in one functional group. The aryl group may be a fused ring cyclic group where each cycle may include the 1 to 3 heteroatoms.

A compound for an organic optoelectronic device according to an embodiment may have a structure including a core moiety including, e.g., a phenylene and three carbazoles, with selected substituents bonded with the core moiety.

At least one of the substituents bonded to the core moiety may be a substituent having improved electron characteristics.

Accordingly, the compound may function as an emission layer by complementing improved hole characteristics of its carbazole structure with electron characteristics. For example, the compound may be used as a host material for an emission layer.

In this specification, hole characteristics refer to a characteristic in which a hole formed in the anode is easily injected into the emission layer and transported in the emission layer due to conductive characteristic according to HOMO level.

In this specification, electron characteristics refer to a characteristic in which an electron formed in the cathode is easily injected into the emission layer and transported in the emission layer due to conductive characteristics according to LUMO level.

The compound for an organic optoelectronic device may include a core moiety and various substituents for substituting the core moiety and thus may have various energy bandgaps. Accordingly, the compound may be used in an electron injection layer (EIL) and transport layer or a hole injection layer (HIL) and transport layer.

The compound may have an appropriate energy level depending on the substituents and thus, may fortify or enhance electron transport capability of an organic photoelectric device and bring about excellent effects on efficiency and driving voltage and also, have excellent electrochemical and thermal stability. Thus, life-span characteristic during the operation of the organic photoelectric device may be improved.

According to an embodiment, a compound for an organic optoelectronic device represented by the following Chemical Formula 1 is provided.

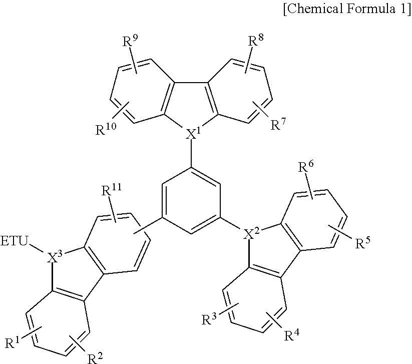

In the above Chemical Formula 1, X¹ to X³ may be N, the ETU may be a substituted or unsubstituted C2 to C30 heteroaryl group having electron characteristics, and R¹ to R¹¹ may each independently be hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

The compound represented by the above Chemical Formula 1 may include carbazole having excellent bipolar characteristics as a portion of the core moiety (e.g., along with a phenylene group).

A substituent having a pi-bond, e.g., in R¹ to R¹¹, may help increase a triplet energy bandgap by controlling a total π-conjugation length of a compound, so as to be very usefully applied to the emission layer of organic photoelectric device as phosphorescent host.

In addition, an appropriate combination of the substituents may provide a compound having excellent thermal stability or resistance against oxidation.

An appropriate combination of the substituents may provide a compound having an asymmetric bipolar characteristic. The asymmetric bipolar characteristic may help improve hole and electron transport capability and thus, may help improve luminous efficiency and performance of a device.

In addition, the substituents may be adjusted or selected to make the structure of a compound bulky and thus, decrease crystallinity of the compound. Accordingly, the compound having low crystallinity may help improve life-span of a device.

As described above, ETU of the compound may be a substituted or unsubstituted C2 to C30 heteroaryl group having electron characteristics.

Examples of the substituted or unsubstituted C2 to C30 heteroaryl group having electron characteristics may include a substituted or unsubstituted imidazolyl group, a substituted or unsubstituted triazolyl group, a substituted or unsubstituted tetrazolyl group, a substituted or unsubstituted oxadiazolyl group, a substituted or unsubstituted oxatriazolyl group, a substituted or unsubstituted thiatriazolyl group, a substituted or unsubstituted benzimidazolyl group, a substituted or unsubstituted benzotriazolyl group, a substituted or unsubstituted pyridinyl group, a substituted or unsubstituted pyrimidinyl group, a substituted or unsubstituted triazinyl group, a substituted or unsubstituted pyrazinyl group, a substituted or unsubstituted pyridazinyl group, a substituted or unsubstituted purinyl group, a substituted or unsubstituted quinolinyl group, a substituted or unsubstituted isoquinolinyl group, a substituted or unsubstituted phthalazinyl group, a substituted or unsubstituted naphpyridinyl group, a substituted or unsubstituted quinoxalinyl group, a substituted or unsubstituted quinazolinyl group, a substituted or unsubstituted acridinyl group, a substituted or unsubstituted phenanthrolinyl group, a substituted or unsubstituted phenazinyl group, or a combination thereof.

In another embodiment, a compound for an organic optoelectronic device represented by the following Chemical Formula 2 is provided. For example, the compound represented by Chemical Formula 1, above, may be represented by Chemical Formula 2, below.

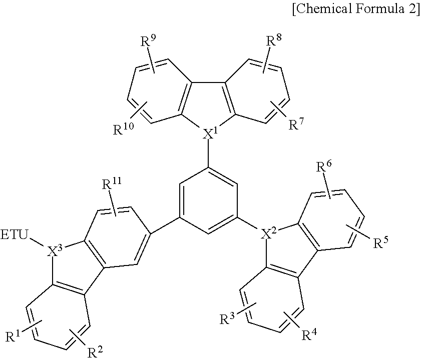

The above Chemical Formula 2 has a structure where a binding position of one carbazole in the above Chemical Formula 1 is limited to one position. Such a structure may maintain wide bandgap characteristics of a carbazole group, and additional substituents having electron transfer/transport characteristics may be introduced.

The substituent having electron characteristics may be the same as described in the above Chemical Formula 1 and thus repeated descriptions thereof are not provided.

As in the above Chemical Formula 1, when the substituent having electron characteristics is boned at a nitrogen position of carbazole, bipolar characteristics of a material may be improved (due to a substituent having electron transfer/transport characteristics) while minimizing changes of conjugation lengths that may cause changes of an energy band.

The compound for an organic optoelectronic device may be represented by one of the following Chemical Formulae 1a to 6a. However, the compound is not limited to the following compounds.

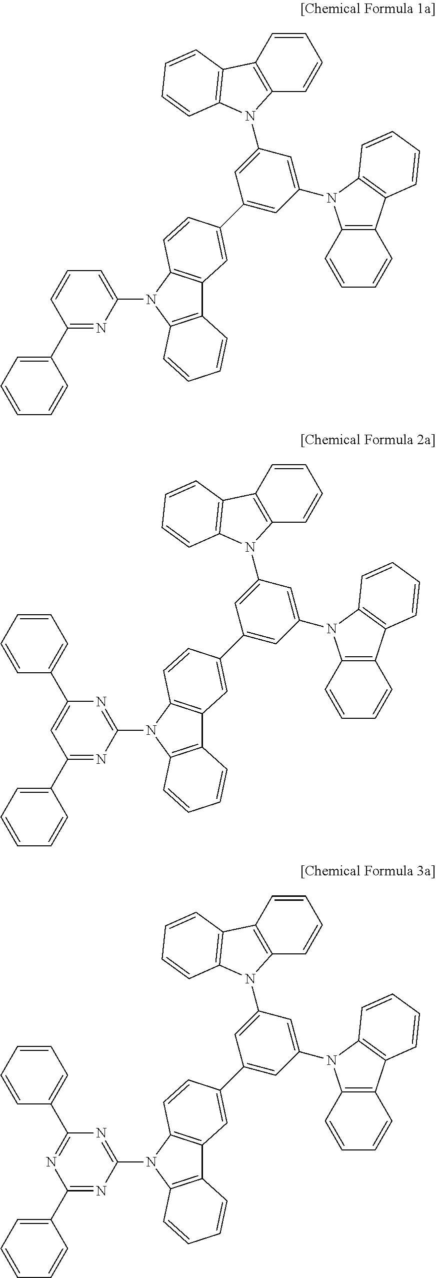 [SMILES: c1ccc(-c2cccc(-n3c4ccccc4c4cc(-c5cc(-n6c7ccccc7c7ccccc76)cc(-n6c7ccccc7c7ccccc76)c5)ccc43)n2)cc1 ; c1ccc(-c2cc(-c3ccccc3)nc(-n3c4ccccc4c4cc(-c5cc(-n6c7ccccc7c7ccccc76)cc(-n6c7ccccc7c7ccccc76)c5)ccc43)n2)cc1 ; c1ccc(-c2nc(-c3ccccc3)nc(-n3c4ccccc4c4cc(-c5cc(-n6c7ccccc7c7ccccc76)cc(-n6c7ccccc7c7ccccc76)c5)ccc43)n2)cc1]

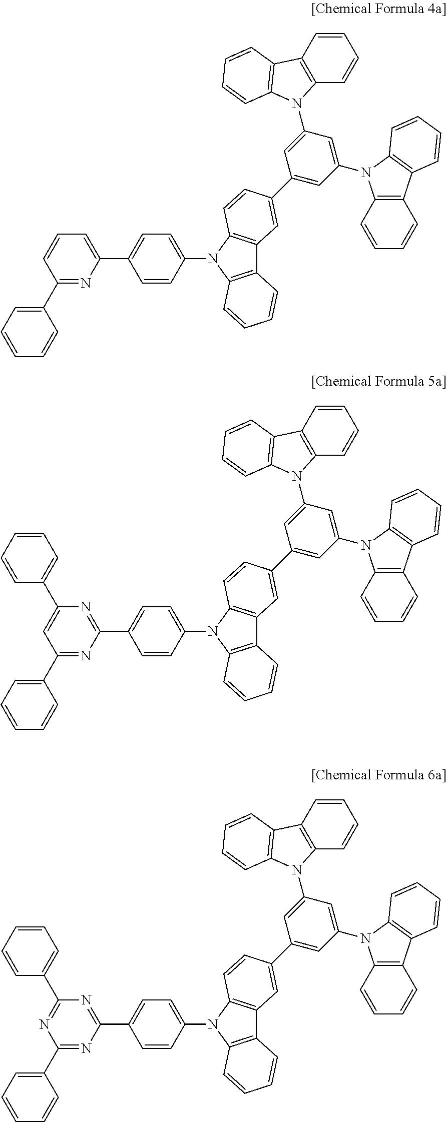 [SMILES: c1ccc(-c2cccc(-c3ccc(-n4c5ccccc5c5cc(-c6cc(-n7c8ccccc8c8ccccc87)cc(-n7c8ccccc8c8ccccc87)c6)ccc54)cc3)n2)cc1 ; c1ccc(-c2cc(-c3ccccc3)nc(-c3ccc(-n4c5ccccc5c5cc(-c6cc(-n7c8ccccc8c8ccccc87)cc(-n7c8ccccc8c8ccccc87)c6)ccc54)cc3)n2)cc1 ; c1ccc(-c2nc(-c3ccccc3)nc(-c3ccc(-n4c5ccccc5c5cc(-c6cc(-n7c8ccccc8c8ccccc87)cc(-n7c8ccccc8c8ccccc87)c6)ccc54)cc3)n2)cc1]

The compound for an organic optoelectronic device (e.g., including any of the above compounds) may have a glass transition temperature of greater than or equal to 110° C. and a thermal decomposition temperature of greater than or equal to 400° C., indicating improved thermal stability. Accordingly, it is possible to produce an organic optoelectronic device having a high efficiency.

The compound for an organic optoelectronic device including the above compounds may play a role for emitting light or injecting and/or transporting electrons, and may also act as a light emitting host with an appropriate dopant. In other words, the compound for an organic optoelectronic device may be used as a phosphorescent or fluorescent host material, a blue light emitting dopant material, or an electron transport material.

The compound for an organic optoelectronic device according to an embodiment may be used for an organic thin layer, and it may help improve the life-span characteristic, efficiency characteristic, electrochemical stability, and thermal stability of an organic photoelectric device and may help decrease the driving voltage.

Therefore, according to another embodiment, an organic optoelectronic device that includes the compound for an organic optoelectronic device is provided. The organic optoelectronic device may include an organic photoelectric device, an organic light emitting diode, an organic solar cell, an organic transistor, an organic photo conductor drum, an organic memory device, and the like. For example, the compound for an organic optoelectronic device according to an embodiment may be included in an electrode or an electrode buffer layer in the organic solar cell to help improve the quantum efficiency, and it may be used as an electrode material for a gate, a source-drain electrode, or the like in the organic transistor.

Hereinafter, an organic light emitting diode is described.

For example, another embodiment provides an organic light emitting diode that includes an anode, a cathode, and at least one organic thin layer between the anode and the cathode. The at least one organic thin layer may include the compound for an organic optoelectronic device according to an embodiment.

The organic thin layer (that may include the compound for an organic optoelectronic device) may include a layer selected from the group of an emission layer, a hole transport layer (HTL), a hole injection layer (HIL), an electron transport layer (ETL), an electron injection layer (EIL), a hole blocking layer, and a combination thereof. The at least one thin layer may include the compound for an organic optoelectronic device according to an embodiment. For example, the compound for an organic optoelectronic device according to an embodiment may be included in an electron transport layer (ETL) or an electron injection layer (EIL). In addition, when the compound for an organic optoelectronic device is included in the emission layer, the compound for an organic optoelectronic device may be included as a phosphorescent or fluorescent host, and particularly, as a fluorescent blue dopant material.

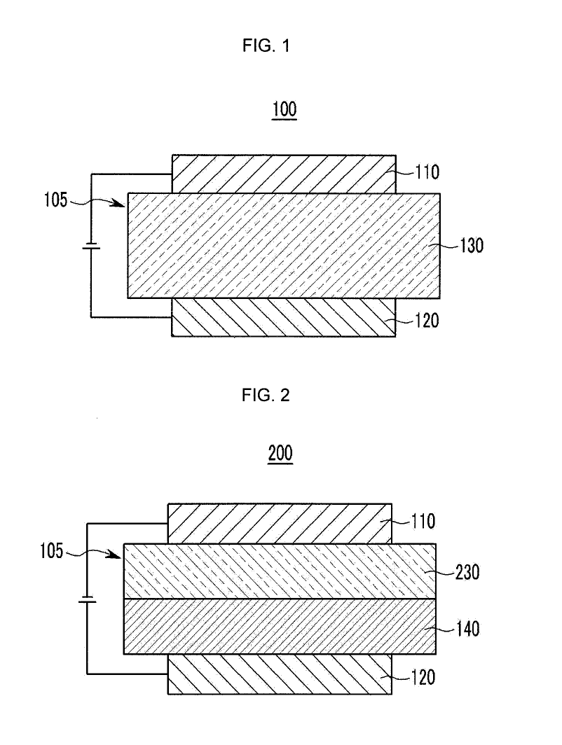

FIGS. 1 to 5 illustrate cross-sectional views showing organic light emitting diodes including the compound for an organic optoelectronic device according to an embodiment.

Referring to FIGS. 1 to 5, organic light emitting diodes 100, 200, 300, 400, and 500 according to an embodiment may include at least one organic thin layer 105 interposed between an anode 120 and a cathode 110.

The anode 120 may include an anode material having a large work function to facilitate hole injection into an organic thin layer. The anode material may include, e.g., a metal such as nickel, platinum, vanadium, chromium, copper, zinc, and gold, or alloys thereof; a metal oxide such as zinc oxide, indium oxide, indium tin oxide (ITO), and indium zinc oxide (IZO); a bonded metal and oxide such as ZnO:Al or SnO₂:Sb; or a conductive polymer such as poly(3-methylthiophene), poly[3,4-(ethylene-1,2-dioxy)thiophene] (PEDT), polypyrrole, and polyaniline, but is not limited thereto. In an implementation, a transparent electrode including indium tin oxide (ITO) may be used as the anode 120.

The cathode 110 may include a cathode material having a small work function to facilitate electron injection into an organic thin layer. The cathode material may include, e.g., a metal such as magnesium, calcium, sodium, potassium, titanium, indium, yttrium, lithium, gadolinium, aluminum, silver, tin, and lead, or alloys thereof; or a multi-layered material such as LiF/Al, Liq/Al, LiO₂/Al, LiF/Ca, LiF/Al, and BaF₂/Ca, but is not limited thereto. In an implementation, a metal electrode including aluminum may be as the cathode 110.

Referring to FIG. 1, the organic optoelectronic device 100 may include an organic thin layer 105 including only an emission layer 130.

Referring to FIG. 2, a double-layered organic photoelectric device 200 may include an organic thin layer 105 including an emission layer 230 including an electron transport layer (ETL), and a hole transport layer (HTL) 140. As shown in FIG. 2, the organic thin layer 105 may include a double layer of the emission layer 230 and hole transport layer (HTL) 140. The emission layer 230 may also function as an electron transport layer (ETL), and the hole transport layer (HTL) 140 layer may have an excellent binding property with a transparent electrode such as ITO or an excellent hole transport capability.

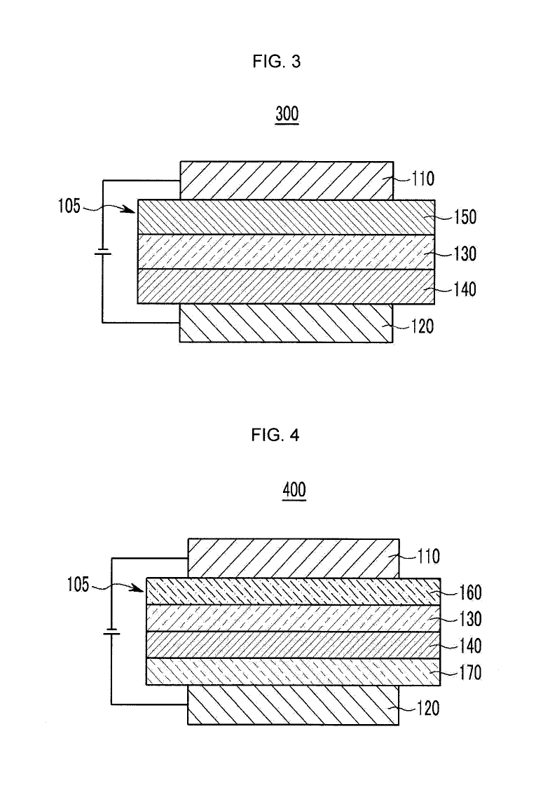

Referring to FIG. 3, a three-layered organic light emitting diode 300 may include an organic thin layer 105 including an electron transport layer (ETL) 150, an emission layer 130, and a hole transport layer (HTL) 140. The emission layer 130 may be independently installed, and layers having an excellent electron transport capability or an excellent hole transport capability may be separately stacked.

As shown in FIG. 4, a four-layered organic optoelectronic device 400 may include an organic thin layer 105 including an electron injection layer (EIL) 160, an emission layer 130, a hole transport layer (HTL) 140, and a hole injection layer (HIL) 170 for adherence with the anode 120 of ITO.

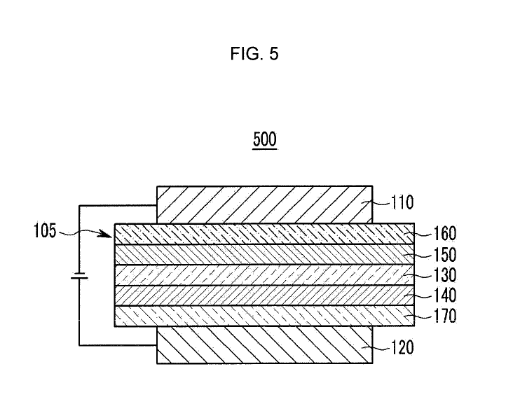

As shown in FIG. 5, a five layered organic light emitting diode 500 may include an organic thin layer 105 including an electron transport layer (ETL) 150, an emission layer 130, a hole transport layer (HTL) 140, and a hole injection layer (HIL) 170, and further includes an electron injection layer (EIL) 160 to achieve a low voltage.

In FIGS. 1 to 5, the organic thin layer 105 including at least one selected from the group of an electron transport layer (ETL) 150, an electron injection layer (EIL) 160, emission layers 130 and 230, a hole transport layer (HTL) 140, a hole injection layer (HIL) 170, and combinations thereof may include the compound for an organic optoelectronic device. The compound for an organic optoelectronic device may be used for an electron transport layer (ETL) 150 including the electron transport layer (ETL) 150 or electron injection layer (EIL) 160. When it is used for the electron transport layer (ETL), it is possible to provide an organic light emitting diode having a more simple structure because it does not require an additional hole blocking layer (not shown).

Furthermore, when the compound for an organic optoelectronic device is included in the emission layers 130 and 230, the material for the organic photoelectric device may be included as a phosphorescent or fluorescent host or a fluorescent blue dopant.

The organic light emitting diode may be fabricated by: forming an anode on a substrate; forming an organic thin layer in accordance with a dry coating method such as evaporation, sputtering, plasma plating, and ion plating or a wet coating method such as spin coating, dipping, and flow coating; and providing a cathode thereon.

Another embodiment provides a display device including the organic light emitting diode according to the above embodiment.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Preparation of Compound for Organic Optoelectronic Device

### Example 1

### Synthesis of Compound Represented by Chemical Formula 3a

A compound represented by the above Chemical Formula 3a as a compound for an organic optoelectronic device was synthesized according to the following Reaction Scheme 1.

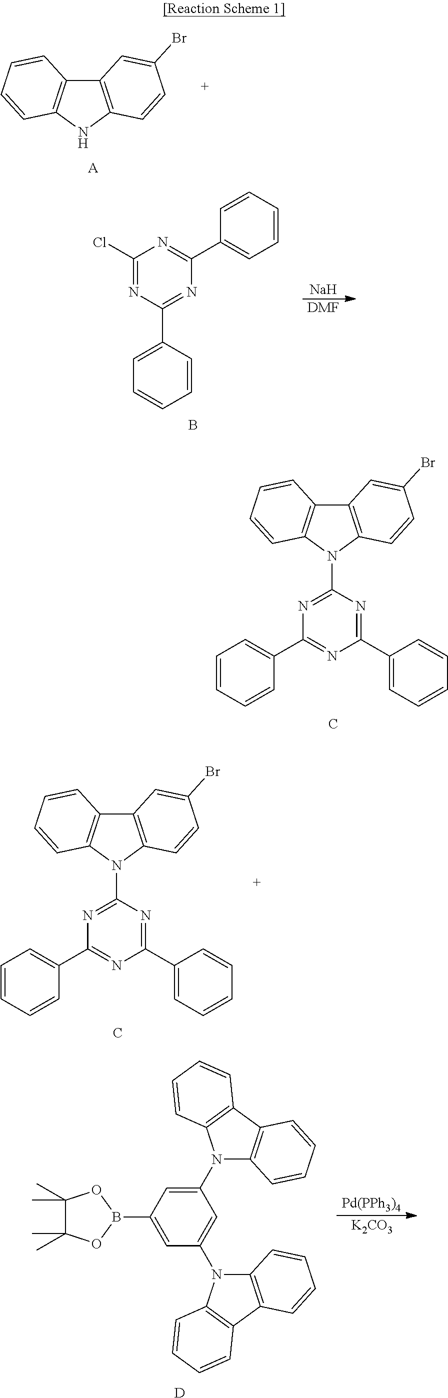

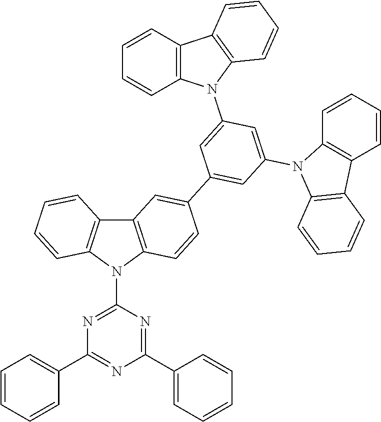 [SMILES: c1ccc(-c2nc(-c3ccccc3)nc(-n3c4ccccc4c4cc(-c5cc(-n6c7ccccc7c7ccccc76)cc(-n6c7ccccc7c7ccccc76)c5)ccc43)n2)cc1]

Synthesis Step 1-1

10.67 g (266.8 mmol) of sodium hydride (NaH) was put in a 2 L round flask, and 100 mL of dimethylformamide (DMF) was added thereto. A solution prepared by dissolving 43.76 g (177.8 mmol) of 3 bromocarbazole (A) in 250 mL of DMF was slowly added to the mixture in a dropwise fashion, and the resultant was agitated at room temperature (˜25° C.) for 40 minutes. 57.13 g (213.4 mmol) of 2-chloro-4,6-diphenyl pyrimidine (B) was dissolved in 250 mL of DMF, the solution was slowly added thereto, and the obtained mixture was agitated for 6 hours. The reactant was poured into water to complete the reaction and a solid produced therein was filtered. The solid was washed with water and methanol and then, heated and dissolved in 400 mL of chlorobenzene, and methane was added thereto for solidification. Then, the solid was filtered and dried in a vacuum oven, obtaining 82.0 g of a compound C (yield: 98%).

Synthesis Step 1-2

A mixture of 1,3,5-tribromobenzene (5.0 g, 15.9 mmol), carbazole (5.8 g, 35.9 mmol), copper(I) iodide (152 mg, 0.8 mmol), 1,10-phenanthroline (288 mg, 1.6 mmol), K₂CO₃ (8.8 g, 64.0 mmol), and 50 mL of dry DMF was refluxed under nitrogen atmosphere for 12 h. After cooling to room temperature, the solvent was removed under vacuum and the residue was extracted with dichloromethane. The product was then obtained by column chromatography on silica gel with 1% ethyl acetate/hexane as the eluent, to get white solid, 9,9′-(5-bromo-1,3-phenylene)bis(9H-carbazole). Isolated yield (3.7 g, 48%).

A mixture of 9,9′-(5-bromo-1,3-phenylene)bis(9H-carbazole) (5.0 g, 10.25 mmol), bis(Pinacolato)diboron (3.1 g, 12.3 mmol), Pd(dppf)Cl₂ (83 mg, 0.1 mmol), potassium acetate (2.5 g, 25.6 mmol), and 50 mL of dry DMF was refluxed under nitrogen atmosphere for 12 h. After cooling to room temperature, the reactant was poured into water to complete the reaction and a solid produced therein was filtered. The solid was washed with water and methanol and then, heated and dissolved in 200 mL of dichloromethane and hexane was added there to for solidification. Then, the solid was filtered and dried in a vacuum oven, obtaining 5.3 g of a compound D (yield: 98%).

Synthesis Step 2

7.51 g (15.7 mmol) of the compound C, 10.09 g (18.9 mmol) of the compound D synthesized in the step 1 and 1.82 g (1.6 mmol) of tetrakis(triphenyl phosphine) palladium (0) were put in a 1 L flask, 150 mL of a 2M potassium carbonate aqueous solution and 150 mL of tetrahydrofuran and 150 mL of toluene as a solvent were added thereto, and the mixture was heated and refluxed for 12 hours under a nitrogen gas stream.

A solid produced during the reaction was filtered. 200 mL of methanol was added to the filtered solution, a solid additionally produced therein was filtered, and the solid and the former obtained solid were washed with 1 L of methanol. The washed solids were heated and dissolved in 100 mL of chlorobenzene, and 200 mL of methanol was added thereto for solidification. Then, a solid produced therein was filtered and dried in a vacuum oven, obtaining 8.90 g of a compound represented by Chemical Formula 3a (yield: 70%). The compound was identified using LC/Mass. [M+H]+ 805.2

### Manufacture of Organic Light Emitting Diode

### Example 2

### Manufacture of Organic Light Emitting Diode Using Compound of Example 1

The compound synthesized in Example 1 was used as a host, and Ir(mppy)₃ was used as a dopant to manufacture an organic light emitting diode.

Specifically, a method of manufacturing the organic photoelectric device included cutting an ITO glass substrate into a size of 50 mm×50 mm×0.7 mm and ultrasonic wave-cleaning it in acetone, isopropyl alcohol, and pure water for 15 minutes respectively and then, UV-ozone cleaning it for 30 minutes.

On the substrate, a 800 Å-thick hole transport layer (HTL) was formed by depositing N,N′-di(1-naphthyl)-N,N′-diphenylbenzidine (NPB) (70 nm) and 4,4′,4″-tri(N-carbazolyl)triphenylamine (TCTA) (10 nm) under conditions of a vacuum degree of 650×10⁻⁷ torr and a deposition rate of 0.1 to 0.3 nm/s.

Then, a 400 Å-thick emission layer was formed thereon using the compound according to Example 1 under the same vacuum deposit conditions, and Ir(mppy)₃ as a phosphorescent dopant was simultaneously deposited. Herein, the deposition rate of the phosphorescent dopant was adjusted to include 10 wt % of the phosphorescent dopant based on 100 wt % of the emission layer.

On the emission layer, bis(8-hydroxy-2-methylquinolinolato)-aluminum biphenoxide (BAlq) was deposited to form a 50 Å-thick hole blocking layer under the same vacuum deposit conditions.

Subsequently, a 200 Å-thick electron transport layer (ETL) was formed thereon by depositing Alq3 under the same vacuum deposit conditions.

On the electron transport layer (ETL), LiF and Al were sequentially deposited to form a cathode, manufacturing an organic light emitting diode.

The organic photoelectric device had a structure of ITO/NPB (70 nm)/TCTA (10 nm)/EML (the compound of Example 1 (90 wt %)+Ir(mppy)3 (10 wt %), 30 nm)/Balq (5 nm)/Alg₃ (20 nm)/LiF (1 nm)/Al (100 nm).

### Comparative Example 1

### Manufacture of Organic Light Emitting Diode Using CBP

An organic light emitting diode was manufactured according to the same method as Example 2 except that carbazolebiphenyl (CBP) was used as a host of an emission layer instead of the compound synthesized in Example 1.

### Performance Measurement of Organic Light Emitting Diode

### Experimental Example

Each organic light emitting diode according to Example 2 and Comparative Example 1 was measured regarding current density and luminance changes depending on voltage and luminous efficiency. The measurements were specifically performed in the following method. The results are provided in the following Table 1.

(1) Measurement of Current Density Change Depending on Voltage Change

The manufactured organic light emitting diodes were measured for current value flowing in the unit device while increasing the voltage from 0 V to 10 V using a current-voltage meter (Keithley 2400), and the measured current value was divided by area to provide the result.

(2) Measurement of Luminance Change Depending on Voltage Change

The manufactured organic light emitting diodes were measured for luminance while increasing the voltage form 0V to 10V using a luminance meter (Minolta Cs1000A).

(3) Measurement of Luminous Efficiency

Current efficiency (cd/A) and electric power efficiency (lm/W) at the same luminance (1,000 cd/m²) were calculated by using luminance and current density from the item (1) and (2) and voltage.

(4) Color Coordinate was Measured Using a Luminance Meter (Minolta Cs1000A), and the Results are Shown.

TABLE 1

| | | | | | Time |
|---|---|---|---|---|---|
| | | Results at 9,000 cd/m² | | | lapsed |
| | | | Electric | | until 10% |
| | Driving | Luminous | Power | Color | luminous |
| | Voltage | Efficiency | Efficiency | Coordinate | efficiency |
| | (V) | (cd/A) | (lm/W) | (x, y) | decreases |
| Example 2 | 5.2 | 56.6 | 34.1 | 0.356, 0.612 | 20 h |
| Comparative | 9.4 | 31.4 | 10.4 | 0.329, 0.629 | 1 h |
| Example 1 | | | | | |

The organic light emitting diode according to Example 2 (using the compound for an organic optoelectronic device of Example 1) exhibited 1.8 improved luminous efficiency and three times or more electric power efficiency than that of Comparative Example 2. In addition, a driving voltage was lowered by more than 4 V.

In terms of life-span, a time lapsed until 10% luminous efficiency decreases exhibited about 20 times difference. That is to say, the compound of the Example 1 improved luminous efficiency and life-span of an organic light emitting diode remarkably.

By way of summation and review, an organic light emitting diode converts electrical energy into light by applying current to an organic light emitting material. It may have a structure in which a functional organic material layer is interposed between an anode and a cathode. The organic material layer may include a multi-layer including different materials, e.g., a hole injection layer (HIL), a hole transport layer (HTL), an emission layer, an electron transport layer (ETL), and an electron injection layer (EIL), in order to help improve efficiency and stability of an organic light emitting diode.

In such an organic light emitting diode, when a voltage is applied between an anode and a cathode, holes from the anode and electrons from the cathode are injected to an organic material layer and recombined to generate excitons having high energy. The generated excitons generate light having certain wavelengths while shifting to a ground state.

A phosphorescent light emitting material may be used for a light emitting material of an organic photoelectric device in addition to the fluorescent light emitting material. Such a phosphorescent material emits lights by transporting the electrons from a ground state to an exited state, non-radiance transiting of a singlet exciton to a triplet exciton through intersystem crossing, and transiting a triplet exciton to a ground state to emit light.

As described above, in an organic light emitting diode, an organic material layer may include a light emitting material and a charge transport material, e.g., a hole injection material, a hole transport material, an electron transport material, an electron injection material, and the like.

The light emitting material may be classified as blue, green, and red light emitting materials according to emitted colors, and yellow and orange light emitting materials to emit colors approaching natural colors.

When one material is used as a light emitting material, a maximum light emitting wavelength may be shifted to a long wavelength or color purity may decrease because of interactions between molecules, or device efficiency may decrease because of a light emitting quenching effect. Thus, a host/dopant system may be included as a light emitting material in order to help improve color purity and increase luminous efficiency and stability through energy transfer.

In order to implement excellent performance of an organic light emitting diode, a material constituting an organic material layer, e.g., a hole injection material, a hole transport material, a light emitting material, an electron transport material, an electron injection material, and a light emitting material such as a host and/or a dopant, should be stable and have good efficiency.

A low molecular weight organic light emitting diode may be manufactured as a thin film in a vacuum deposition method, and can have good efficiency and life-span performance. A polymer organic light emitting diode manufactured in an Inkjet or spin coating method may have an advantage of low initial cost and being large-sized.

Both low molecular weight organic light emitting and polymer organic light emitting diodes have an advantage of self-light emitting, high speed response, wide viewing angle, ultra-thinness, high image quality, durability, large driving temperature range, and the like. In particular, they have good visibility due to the self-light emitting characteristic compared with a conventional LCD (liquid crystal display) and have an advantage of decreasing thickness and weight of an LCD by up to a third, because they do not need a backlight.

In addition, since they have a response speed of a microsecond unit, which is 1,000 times faster than an LCD, they can realize a perfect motion picture without an after-image. Based on these advantages, they have been remarkably developed to have 80 times the efficiency and more than 100 times the life-span since they first came out in the late 1980s. Recently, they have become rapidly larger such that a 40-inch organic light emitting diode panel is now possible.

They should simultaneously exhibit improved luminous efficiency and life-span in order to be larger. Luminous efficiency may require smooth combination between holes and electrons in an emission layer. However, since an organic material in general may have slower electron mobility than hole mobility, inefficient combination between holes and electrons may occur. Accordingly, increasing electron injection and mobility from a cathode and simultaneously preventing movement of holes may be desirable.

The embodiments provide a compound for an organic optoelectronic device that may act as a light emitting or electron injection and transport material, and also act as a light emitting host along with an appropriate dopant.

The embodiments provide an organic light emitting diode having excellent life-span, efficiency, driving voltage, electrochemical stability, and thermal stability.

The embodiments provide an organic optoelectronic device having excellent electrochemical and thermal stability and life-span characteristics, and high luminous efficiency at a low driving voltage.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A compound for an organic optoelectronic device, the compound being represented by the following Chemical Formula 1: 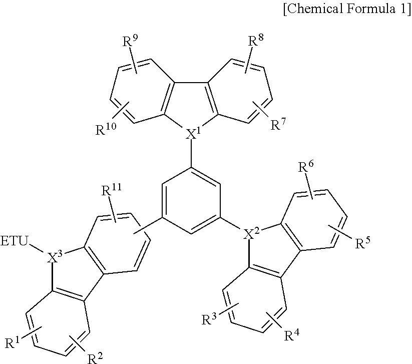
wherein, in the above Chemical Formula 1,
X¹ to X³ are N,
ETU is a substituted or unsubstituted C2 to C30 heteroaryl group having electron characteristics, and
R¹ to R¹¹ are each independently hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

2. The compound for an organic optoelectronic device as claimed in claim 1, wherein the compound for an organic optoelectronic device is represented by the following Chemical Formula 2: 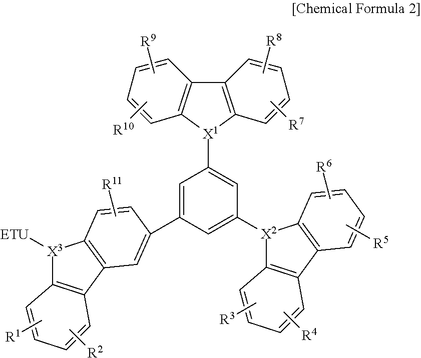
wherein, in the above Chemical Formula 2,
X¹ to X³ are N,
ETU is a substituted or unsubstituted C2 to C30 heteroaryl group having electron characteristics, and
R¹ to R¹¹ are each independently hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

3. The compound for an organic optoelectronic device as claimed in claim 1, wherein the substituted or unsubstituted C2 to C30 heteroaryl group having electron characteristics is a substituted or unsubstituted imidazolyl group, a substituted or unsubstituted triazolyl group, a substituted or unsubstituted tetrazolyl group, a substituted or unsubstituted oxadiazolyl group, a substituted or unsubstituted oxatriazolyl group, a substituted or unsubstituted thiatriazolyl group, a substituted or unsubstituted benzimidazolyl group, a substituted or unsubstituted benzotriazolyl group, a substituted or unsubstituted pyridinyl group, a substituted or unsubstituted pyrimidinyl group, a substituted or unsubstituted triazinyl group, a substituted or unsubstituted pyrazinyl group, a substituted or unsubstituted pyridazinyl group, a substituted or unsubstituted purinyl group, a substituted or unsubstituted quinolinyl group, a substituted or unsubstituted isoquinolinyl group, a substituted or unsubstituted phthalazinyl group, a substituted or unsubstituted naphpyridinyl group, a substituted or unsubstituted quinoxalinyl group, a substituted or unsubstituted quinazolinyl group, a substituted or unsubstituted acridinyl group, a substituted or unsubstituted phenanthrolinyl group, a substituted or unsubstituted phenazinyl group, or a combination thereof.

4. The compound for an organic optoelectronic device as claimed in claim 1, wherein the organic optoelectronic device is selected from an organic photoelectric device, an organic light emitting diode, an organic solar cell, an organic transistor, an organic photo-conductor drum, and an organic memory device.

5. A compound for an organic optoelectronic device, the compound being represented by one of the following Chemical Formulae 1a to 6a:

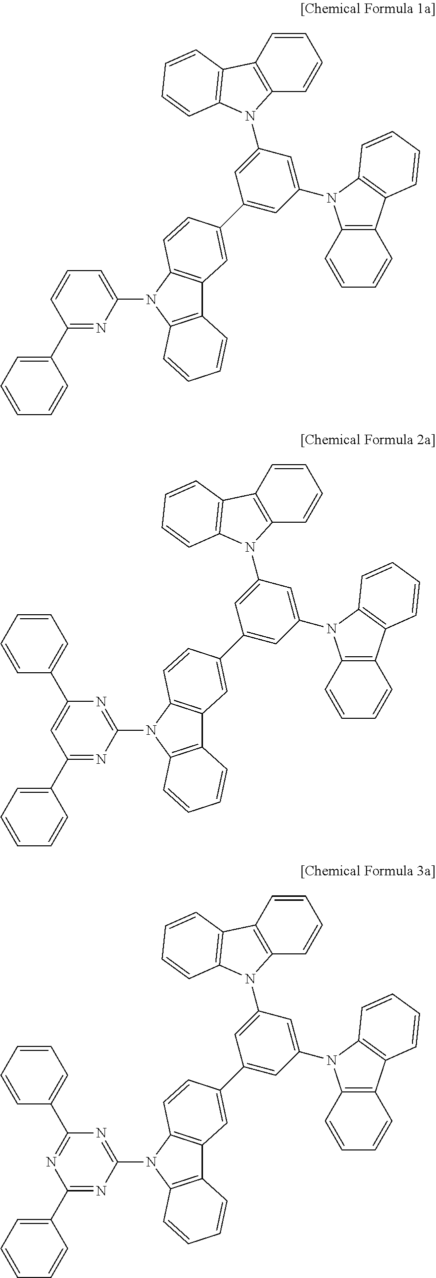 [SMILES: c1ccc(-c2cccc(-n3c4ccccc4c4cc(-c5cc(-n6c7ccccc7c7ccccc76)cc(-n6c7ccccc7c7ccccc76)c5)ccc43)n2)cc1 ; c1ccc(-c2cc(-c3ccccc3)nc(-n3c4ccccc4c4cc(-c5cc(-n6c7ccccc7c7ccccc76)cc(-n6c7ccccc7c7ccccc76)c5)ccc43)n2)cc1 ; c1ccc(-c2nc(-c3ccccc3)nc(-n3c4ccccc4c4cc(-c5cc(-n6c7ccccc7c7ccccc76)cc(-n6c7ccccc7c7ccccc76)c5)ccc43)n2)cc1]

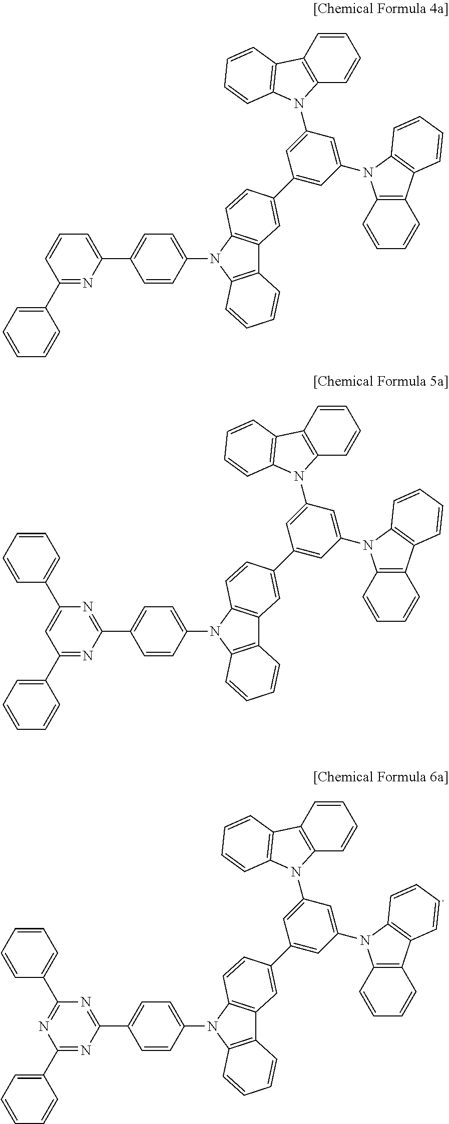 [SMILES: c1ccc(-c2cccc(-c3ccc(-n4c5ccccc5c5cc(-c6cc(-n7c8ccccc8c8ccccc87)cc(-n7c8ccccc8c8ccccc87)c6)ccc54)cc3)n2)cc1 ; c1ccc(-c2cc(-c3ccccc3)nc(-c3ccc(-n4c5ccccc5c5cc(-c6cc(-n7c8ccccc8c8ccccc87)cc(-n7c8ccccc8c8ccccc87)c6)ccc54)cc3)n2)cc1 ; c1ccc(-c2nc(-c3ccccc3)nc(-c3ccc(-n4c5ccccc5c5cc(-c6cc(-n7c8ccccc8c8ccccc87)cc(-n7c8ccccc8c8ccccc87)c6)ccc54)cc3)n2)cc1]

6. An organic light emitting diode, comprising:
an anode, a cathode, and at least one organic thin layer between the anode and the cathode,
wherein the at least one organic thin layer includes the compound for an organic optoelectronic device as claimed in claim 1.

7. The organic light emitting diode as claimed in claim 6, wherein the at least one organic thin layer is selected from an emission layer, a hole transport layer (HTL), a hole injection layer (HIL), an electron transport layer (ETL), an electron injection layer (EIL), a hole blocking layer, and a combination thereof.

8. The organic light emitting diode as claimed in claim 6, wherein:
the at least one organic thin layer includes an electron transport layer (ETL) or an electron injection layer (EIL), and
the compound for an organic optoelectronic device is included in the electron transport layer (ETL) or the electron injection layer (EIL).

9. The organic light emitting diode as claimed in claim 6, wherein:
the at least one organic thin layer includes an emission layer, and
the compound for an organic optoelectronic device is included in the emission layer.

10. The organic light emitting diode as claimed in claim 6, wherein:
the at least one organic thin layer includes an emission layer, and
the compound for an organic optoelectronic device is a phosphorescent or fluorescent host material in the emission layer.

11. The organic light emitting diode as claimed in claim 6, wherein:
the at least one organic thin layer includes an emission layer, and
the compound for an organic optoelectronic device is a fluorescent blue dopant material in the emission layer.

12. A display device comprising the organic light emitting diode as claimed in claim 6.
